(19) United States
(12) Patent Application Publication
(10) Pub. No.: US 2010/0243435 A1
(43) Pub. Date: Sep. 30, 2010

(54) Sputtering Target for Magnetic Recording Film and Method for Manufacturing the Same

(75) Inventor: Kazuteru Kato, Omuta-shi (JP)

Correspondence Address: THE WEBB LAW FIRM, P.C., 700 KOPPERS BUILDING, 436 SEVENTH AVENUE, PITTSBURGH, PA, 15219, US

(73) Assignee: MITSUI MINING & SMELTING CO., LTD., Tokyo (JP)

(21) Appl. No.: 12/739,261

(22) PCT Filed: Oct. 21, 2008
(86) PCT No.: PCT/JP2008/069021

§ 371 Date: Apr. 22, 2010

(30) Foreign Application Priority Data
Oct. 24, 2007 (JP) 2007-276570

(51) Int. Cl. C23C 14/34; B22F 3/10

(52) U.S. Cl. 204/298.03; 204/298.13; 419/19

(57) ABSTRACT

Provided is a sputtering target for a magnetic recording film, in which film formation efficiency and film characteristics can be improved by suppressing growth of crystal grains, reducing magnetic permeability, and increasing density. A method for manufacturing such a sputtering target is also provided. The sputtering target is composed of a matrix phase which includes Co and Pt and a metal oxide phase for example. The sputtering target has a magnetic permeability in the range of 6 to 15 and a relative density of 90% or more.

### TECHNICAL FIELD

The present invention relates to a sputtering target that is used in the case in which a magnetic recording film is formed and a method for manufacturing the sputtering target. More specifically, the present invention relates to a sputtering target for a magnetic recording film that has a low magnetic permeability and a high density and a method for manufacturing the sputtering target.

### BACKGROUND ART

A hard disk device that is adopted as an external recording device requires a high density recording performance that can be corresponded to a high performance computer and digital consumer electronics and so on. In recent years, the perpendicular magnetic recording technology that satisfies such a high density recording performance has been getting noticed. As a perpendicular magnetization film that is used for the perpendicular magnetic recording technology, an alloy magnetic film of Co series is adopted in a variety of ways. It is known that a media noise can be reduced and a recording density can be improved in the case in which a size and dispersion for crystal grains of each phase are suppressed and a magnetic interaction between crystal grains is reduced for the magnetic film.

Such an alloy magnetic film of Co series can be obtained by sputtering a sputtering target at the present days. For the method, a wide variety of research and development are carried out to improve a quality of a sputtering target being used in order to implement a high density recording performance and a high magnetic coercive force for a film that is obtained.

For instance, Patent document 1 discloses a sputtering target made of a Co series alloy. The sputtering target is a target in which an alloy phase and a ceramics phase are uniformly dispersed in order to implement an improvement of a magnetic coercive force for an alloy magnetic film of Co series and a reduction of a noise. The sputtering target has a mixed phase that is fine to some extent and indicates a high relative density. However, since a sintering temperature in manufacturing the target is relatively high in the range of 1000 to 1300° C., a growth of a crystal grain is not fully suppressed. Consequently, it is necessary to further improve a magnetic permeability.

Moreover, Patent document 2 discloses a sputtering target that includes a metal phase that contains at least Co and a ceramics phase. The sputtering target has a high density, in which a relative density is 99% or higher. However, a long axis grain diameter of an oxide phase is 10 μm or less. It is thought that this is caused by a high sintering temperature in the range of 1150 to 1250° C. A growth of a crystal grain is also not fully suppressed for the sputtering target.

On the other hand, Patent document 3 discloses a sputtering target for a magnetic recording medium in a surface of a high density, which is composed of an alloy phase that includes Co and a ceramics phase in order to implement an improvement of a magnetic coercive force and a reduction of a media noise. The sputtering target is a target in which an alloy phase and a ceramics phase are finely and uniformly dispersed, whereby particles can be reduced. However, a density of the target is not examined in the concrete, and it is necessary to further improve a magnetic permeability.

Patent document 1: Japanese Patent Application Laid-Open Publication No. 10-88333
Patent document 2: Japanese Patent Application Laid-Open Publication No. 2006-45587
Patent document 3: Japanese Patent Application Laid-Open Publication No. 2006-313584

### DISCLOSURE OF THE INVENTION

### Problems to be Solved by the Invention

Any sputtering target that has been described above cannot fully satisfy all of qualities of a suppression of a growth of a crystal grain, a low magnetic permeability, and a high density.

An object of the present invention is to provide a sputtering target in which the above qualities can be maintained in a balanced manner, that is, a sputtering target for a magnetic recording film in which a film formation efficiency and film characteristics can be improved by suppressing a growth of crystal grains, by reducing magnetic permeability, and by increasing a density, and to provide a method for manufacturing the sputtering target.

### Means For Solving the Problems

The sputtering target for a magnetic recording film in accordance with the present invention is characterized by comprising a matrix phase that includes Co and Pt and a metal oxide phase, wherein a magnetic permeability is in the range of 6 to 15 and a relative density is 90% or higher.

The sputtering target for a magnetic recording film in accordance with the present invention is also characterized in that an average grain diameter of a grain made of the matrix phase and an average grain diameter of a grain made of the metal oxide phase are both at least 0.05 μm and less than 7.0 μm, and an average grain diameter of a grain made of the matrix phase is larger than an average grain diameter of a grain made of the metal oxide phase in the case in which a surface of the sputtering target is observed by using a scanning analytical electron microscope.

The sputtering target for a magnetic recording film in accordance with the present invention is preferably characterized in that an X-ray diffraction peak intensity ratio that is represented by the following expression (I) is in the range of 0.7 to 1.0 for an X-ray diffraction analysis.

[Expression (I)]

X-ray diffraction peak intensity ratio=X-ray diffraction peak intensity of the Co-fcc [002] face/{(X-ray diffraction peak intensity of the Co-hcp [103] face+X-ray diffraction peak intensity of the Co-fcc [002] face)} (I)

The sputtering target for a magnetic recording film in accordance with the present invention is also characterized in that the metal oxide phase includes an oxide of at least one kind of an element that is selected from Si, Ti, and Ta, and the matrix phase further includes Cr.

The sputtering target for a magnetic recording film in accordance with the present invention is preferably characterized in that the sputtering target is obtained by carrying out a sintering at a sintering temperature in the range of 800 to 1050° C., and the sputtering target is obtained by carrying out a sintering based on an electric current sintering.

A method for manufacturing a sputtering target for a magnetic recording film in accordance with the present invention is characterized by comprising a matrix phase that includes Co and Pt and a metal oxide phase, wherein a magnetic permeability is in the range of 6 to 15 and a relative density is 90% or higher, and the method for manufacturing the sputtering target in accordance with the present invention is characterized by comprising the steps of powdering a metal that includes Co and Pt and a metal oxide, sintering the powder at a sintering temperature in the range of 800 to 1050° C., and lowering a temperature at a rate in the range of 300 to 1000° C./hr.

### EFFECT OF THE INVENTION

The sputtering target for a magnetic recording film in accordance with the present invention is a sputtering target that has a high density and in which a growth of a crystal grain is fully suppressed. Consequently, an occurrence of a particle and an arcing can be reduced. Moreover, the sputtering target has a low magnetic permeability, thereby improving a sputter rate. In addition, a high speed film formation can be implemented in the case in which the sputtering target is sputtered to form a magnetic recording film.

Moreover, by the method for manufacturing a sputtering target for a magnetic recording film in accordance with the present invention, the sputtering target can be obtained easily at a high speed, whereby the efficiency for manufacturing processes can be improved.

### BRIEF DESCRIPTION OF THE DRAWINGS

FIG. 1 is a view showing an SEM image of a cutting plane of a sputtering target that is obtained in the Embodiment 3.

FIG. 2 is a view showing an SEM image of a cutting plane of a sputtering target that is obtained in the Embodiment 7.

FIG. 3 is a view showing an SEM image of a cutting plane of a sputtering target that is obtained in the comparative example 3.

FIG. 4 is a view showing an SEM image of a cutting plane of a sputtering target that is obtained in the comparative example 4.

### BEST MODE OF CARRYING OUT THE INVENTION

A sputtering target for a magnetic recording film and a method for manufacturing the sputtering target in accordance with the present invention will be described below in detail.

### <Sputtering Target for a Magnetic Recording Film>

The sputtering target for a magnetic recording film in accordance with the present invention (hereafter also referred to as a sputtering target in accordance with the present invention) is characterized by comprising a matrix phase that includes Co and Pt and a metal oxide phase, wherein a magnetic permeability is in the range of 6 to 15 and a relative density is 90% or higher.

The matrix phase is composed of Co and Pt. Most commonly, the matrix phase includes Co of an amount in the range of 1 to 80 mole %, preferably 1 to 75 mole %, more preferably 1 to 70 mole %, and Pt of an amount in the range of 1 to 20 mole %, preferably 1 to 15 mole %, more preferably 5 to 15 mole % in 100 mole % of the target. As the metal, Cr of an amount in the range of 1 to 20 mole %, preferably 1 to 15 mole %, more preferably 5 to 15 mole % can also be further contained.

The metal oxide phase is made of an oxide of a metal element. Most commonly, the metal oxide phase of an amount in the range of 0.01 to 20 mole %, preferably 0.01 to 15 mole %, more preferably 0.01 to 10 mole % in 100 mole % of the target is included.

As a metal oxide, there can be mentioned for instance SiO, SiO₂, TiO₂, Ta₂O₅, Al₂O₃, MgO, CaO, Cr₂O₃, ZrO₂, B₂O₃, Sm₂O₃, HfO₂, and Gd₂O₃ to be more precise. In particular, the metal oxide is preferably an oxide of at least an element of the first kind that is selected from Si, Ti, and Ta. A remaining part can contain other elements without spoiling the effect of the present invention. As the other elements, tantalum, niobium, copper, and neodymium can be mentioned for instance.

The metal oxide phase also includes a small amount of an oxide that has been generated by oxidizing a metal that configures a matrix phase in the air or during sintering in some cases in addition to the above metal oxide. For instance, in the case in which Cr is included as a metal, a part thereof can exist as Cr₂O₃ in the metal oxide phase.

Co that is included in the matrix phase has the characteristics that can be in a magnetic state or in a nonmagnetic state. However, since Co can be easily in a nonmagnetic state in the case in which the metal phase is uniformly dispersed, a magnetic permeability that is one of important physical properties for a target can be reduced. A magnetic permeability of a sputtering target in accordance with the present invention is generally in the range of 6 to 15, preferably in the range of 6 to 12, more preferably in the range of 6 to 9. In the case in which the target has a low magnetic permeability, a leakage flux becomes higher, whereby a sputtering rate can be improved and a high speed film formation can be easily carried out. Moreover, the duration of life of the target can be lengthened, and a mass productivity per one target can be improved.

A relative density of the sputtering target in accordance with the present invention is a value that is measured based on the Archimedes method for the sputtering target after being sintered, and is generally 90% or higher, preferably 95% or higher, more preferably 97% or higher. Although the upper limit of the relative density is not restricted in particular, the relative density is up to 100% by ordinary. In the case in which the target has the above value of the relative density, so-called high density, a target breaking caused by a thermal shock or a difference in temperature when the sputtering of the target is carried out can be prevented, and a thickness of the target can be effectively utilized without waste. In addition, an occurrence of a particle and an arcing can be effectively reduced, and a sputtering rate can be improved. Consequently, a loss in a continuous production can be suppressed, and the number of formed films per unit area of the target can be increased, whereby a high speed film formation can be implemented.

The Archimedes method is a method for obtaining a relative density (%) that is defined by a percentage to a theoretical density ρ (g/cm³) that is represented by the following expression in the case in which an aerial weight of a target sintered object is divided by a volume (=weight in water for a target sintered object/water specific gravity at a measured temperature).

$$\begin{matrix}[ Expression 3 ] & \\ ρ ≡ {( \frac{{C}_{1} / 100}{{ρ}_{1}} + \frac{{C}_{2} / 100}{{ρ}_{2}} + … + \frac{{C}_{i} / 100}{{ρ}_{i}} )}^{- 1} & ( X )\end{matrix}$$

(In the expression (X), C1 to Ci represent a content (% by weight) of a component material of a target sintered object, and ρ to ρi represent a density (g/cm³) of each component material corresponded to C1 to Ci.)

The sputtering target that has such a high density enables a specific resistance of a formed film to be reduced. Consequently, in the case in which the sputtering target in accordance with the present invention is sputtered, a magnetic recording film that has a stable film characteristic can be formed.

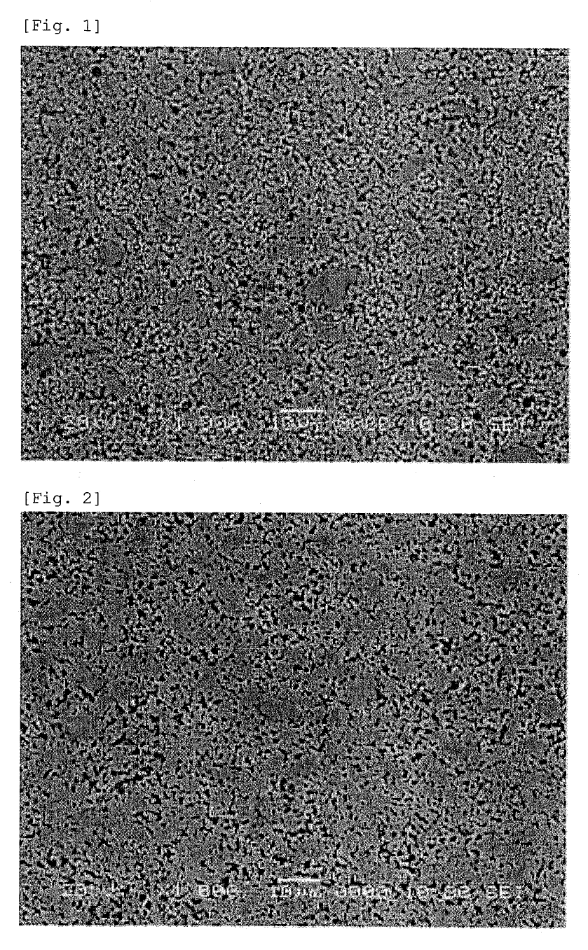

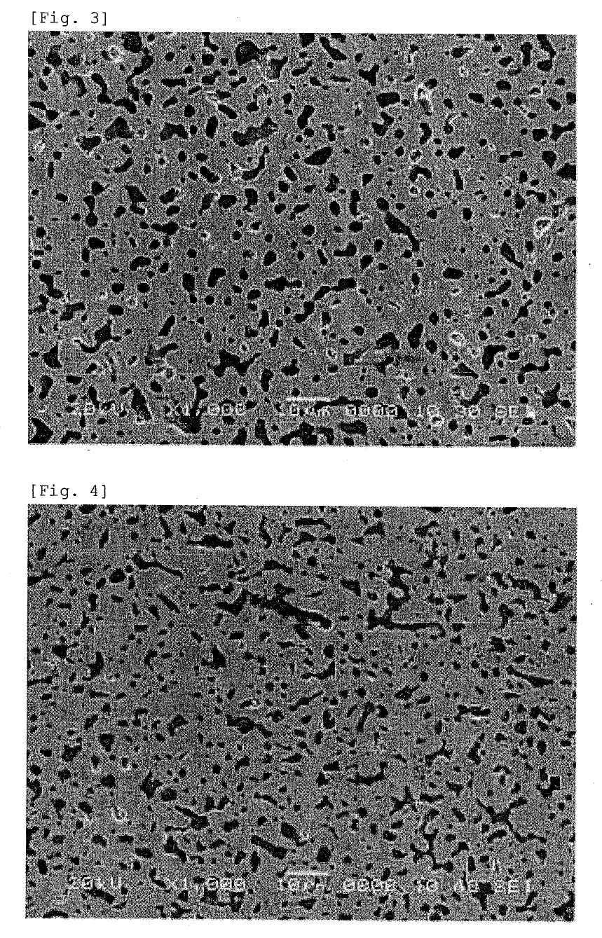

For the sputtering target that is composed of the above components, grains are formed for both the matrix phase and the metal oxide phase. As shown in FIG. 1 for instance, in the case in which the surface of the target is observed by using a scanning analytical electron microscope (SEM), grains made of the metal oxide phase are indicated by a black color, and other grains are made of the matrix phase. For the sputtering target in accordance with the present invention, an average grain diameter of a grain made of the matrix phase and an average grain diameter of a grain made of the metal oxide phase are generally at least 0.05 μm and less than 7.0 μm, preferably in the range of 0.05 to 6.0 μm, more preferably in the range of 0.5 to 6.0 μm. The average grain diameter means a value that is obtained by observing a cutting plane of a sputtering target by using a scanning analytical electron microscope (SEM), drawing a diagonal line in a visual field of thousand magnifications of a SEM image, measuring a maximum grain diameter and a minimum grain diameter for each of grains made of the matrix phase and the metal oxide phase that exist on the diagonal line, and averaging the maximum grain diameter and the minimum grain diameter.

Moreover, an average grain diameter of a grain made of the matrix phase is larger than an average grain diameter of a grain made of the metal oxide phase on a constant basis.

In the case in which an average grain diameter of a fine grain made of the matrix phase and an average grain diameter of a fine grain made of the metal oxide phase are in the above range and an average grain diameter of a grain made of the matrix phase is larger than an average grain diameter of a grain made of the metal oxide phase, the grains are fully dispersed, and the state in which a grain growth of the grain is effectively reduced, that is, the state in which the matrix phase and the metal oxide phase are uniformly dispersed can be maintained. Moreover, in the case in which a sputtering target is sputtered to form a film, a particle that is generated in the case in which the solution metal oxide phase in a massive form adheres to the film in particular can be effectively reduced, and an occurrence of an arcing can also be suppressed. Furthermore, the homogeneity and a denseness of a film to be obtained can be also improved.

The sputtering target for a magnetic recording film in accordance with the present invention is characterized in that an X-ray diffraction peak intensity ratio that is represented by the following expression (I) is generally in the range of 0.7 to 1.0, preferably in the range of 0.8 to 1.0 for an X-ray diffraction analysis.

[Expression 2]

X-ray diffraction peak intensity ratio=X-ray diffraction peak intensity of the Co-fcc [002] face/{(X-ray diffraction peak intensity of the Co-hcp [103] face+X-ray diffraction peak intensity of the Co-fcc [002] face)} (I)

In the present specification, the X-ray diffraction peak of the Co-fcc [002] face means a peak that appears around 28=51° in the case in which Cu is used as an X-ray source. Moreover, the X-ray diffraction peak of the Co-hcp [103] face means a peak that appears around 28=82° in the case in which Cu is used as an X-ray source. Furthermore, the X-ray diffraction peak intensity means a value that is obtained by simply multiplying a peak height by a half value width (peak height×half value width).

A crystal that exists in a matrix phase that includes Co and Pt in accordance with the present invention forms an fcc structure (a cubic closest packed structure) or an fcp structure (a hexagonal closest packed structure). A phase transition between the above crystal structures can be carried out. In the case in which a crystal that exists in a matrix phase forms an fcc structure, the X-ray diffraction peak of the Co-fcc [002] face appears around 2θ=51°. In the case in which a crystal that exists in a matrix phase forms an hcp structure, the X-ray diffraction peak of the Co-hcp [103] face appears around 2θ=82°. Consequently, in the case in which a value of an X-ray diffraction peak intensity ratio that is represented by the expression (I) is in the above range, the fcc structures to be formed are more than the fcp structures to be formed for the matrix phase. That many crystals that form the fcc structure exist in the matrix phase of the sputtering target in accordance with the present invention is estimated to contribute to a reduction of a magnetic permeability for a target to be obtained.

A sintering temperature of the sputtering target in accordance with the present invention is generally in the range of 800 to 1050° C., preferably in the range of 900 to 1050° C., more preferably in the range of 950 to 1050° C. although the sintering temperature can be affected by a composition of the target as described later. In the case in which a sintering temperature is in the above range, the sintering can be carried out at a relatively low temperature, and a density of the target to be obtained is not reduced more than necessary. By carrying out the sintering at such a low temperature, it is possible to obtain the sputtering target in which a grain growth of the fine grain that is formed by the above matrix phase and the above metal oxide phase is effectively suppressed.

It is preferable that a temperature of the sputtering target that has been obtained by sintering at the above sintering temperature is lowered from the above sintering temperature to 200° C. at a rate generally in the range of 300 to 1000° C./hr, preferably in the range of 500 to 1000° C./hr, more preferably in the range of 700 to 1000° C./hr. In the case in which the temperature lowering rate is in the above range, a temperature can be rapidly lowered, and a grain growth of the fine grain that is formed by the above matrix phase and the above metal oxide phase can be effectively suppressed.

The fcc structure that is formed by a crystal that exists in a matrix phase that includes Co and Pt can exist in a stable manner in a higher temperature region as compared with the hcp structure that is formed by the same crystal. However, in the case in which a temperature is rapidly lowered as described above, it is estimated that a crystal that has formed the fcc structure can be sealed off, a phase transition to the hcp structure can be suppressed, and a crystal grain that is provided with the fcc structure can be effectively held. Consequently, it is thought that many of crystals that exist in a matrix phase of the sputtering target in accordance with the present invention are provided with the fcc structure, and the crystals indicate the X-ray diffraction peak intensity ratio as described above.

A sintering method is not restricted in particular, providing the sintering method satisfies the above conditions of a sintering temperature and a temperature lowering rate. However, an electric current sintering is preferable. By the electric current sintering, a low temperature sintering can be enabled and a high speed temperature lowering can be easily controlled.

The electric current sintering is a method for sintering by applying a large amount of an electric current under the conditions of an increased pressure and an applied voltage. The electric current sintering includes a discharge plasma sintering method, a discharge sintering method, and a plasma activation sintering method. For the present method, sintering is accelerated by an electrolytic diffusion effect caused by an electric field and an activating action on the surface of a grain due to discharge plasma or the like, a thermal diffusion effect caused by a Joule heat, and a plastic deformation pressure caused by an application of pressure as driving force of sintering by utilizing a discharge phenomenon that occurs in a gap between raw powders. By using the present method, a molded body (a raw powder) can be fully sintered even in a low temperature range around the above sintering temperature.

### <Magnetic Recording Film>

A sputtering target in accordance with the present invention is suitably used for forming a magnetic recording film, in particular a perpendicular magnetization film. The perpendicular magnetization film is a recording film based on the perpendicular magnetic recording technology in which the axis of easy magnetization is oriented in a direction mainly perpendicular to a nonmagnetic substrate in order to improve a recording density. By sputtering the sputtering target in accordance with the present invention, a high speed film formation for a magnetic recording film of a high quality can be carried out.

As a sputtering system that is adopted for a film formation, a DC magnetron sputtering system or an RF magnetron sputtering system are suitable most commonly. Although a thickness of a film is not restricted in particular, a thickness of a film is generally in the range of 5 to 100 nm, preferably in the range of 5 to 20 nm.

The magnetic recording film that is obtained as described above can contain Co and Pt at a relative proportion of at least approximately 95% of a target compositional ratio. Moreover, while keeping the relation in which an average grain diameter of a grain that is formed by the matrix phase is larger than an average grain diameter of a grain that is formed by the metal oxide phase, the magnetic recording film can be obtained from the sputtering system in accordance with the present invention in which a size of a grain that is formed by the matrix phase and the metal oxide phase is reduced. Consequently, the homogeneity and a denseness of the magnetic recording film can be improved. Moreover, the magnetic recording film is excellent in not only a magnetic coercive force but also magnetic characteristics such as a perpendicular magnetic anisotropy and a perpendicular antimagnetic force. Consequently, the magnetic recording film can be suitably used as a perpendicular magnetization film in particular.

### <Method for Manufacturing the Sputtering Target for a Magnetic Recording Film>

A method for manufacturing a sputtering target for a magnetic recording film in accordance with the present invention is characterized by comprising a matrix phase that includes Co and Pt and a metal oxide phase, wherein a magnetic permeability is in the range of 6 to 15 and a relative density is 90% or higher, and the method for manufacturing the sputtering target in accordance with the present invention is characterized by comprising the steps of forming a powder composed of a metal that includes Co and Pt and a metal oxide, sintering the powder at a sintering temperature in the range of 800 to 1050° C., and lowering a temperature at a rate in the range of 300 to 1000° C./hr.

To obtain a sputtering target in accordance with the present invention, a powder composed of a metal that includes Co and Pt and a metal oxide is used. As the powder, a powder (B) that is obtained from a powder (A) is used according to the following method.

The powder (A) is obtained by a mechanical alloying process of Co and a metal oxide. In the case in which Cr is contained as a metal, it is preferable that an alloy of Co and Cr is atomized at first. For an alloy that is used as a raw material in this case, a Cr concentration is generally in the range of 5 to 95 atom %, preferably in the range of 10 to 70 atom %. A powder can be obtained by atomizing the alloy.

An atomizing method is not restricted in particular, and the atomizing method can be any one of a water atomizing method, a gas atomizing method, a vacuum atomizing method, and a centrifugal atomizing method. Among them, the gas atomizing method is preferable. A tapping temperature is generally in the range of 1420 to 1800° C., preferably in the range of 1420 to 1600° C. In the case in which the gas atomizing method is used, an N₂ gas or an Ar gas is injected most commonly. In the case in which an Ar gas is injected, the oxidization can be preferably suppressed, and a powder in a spherical shape can be obtained. By atomizing the above alloy, it is possible to obtain an atomized powder having an average grain diameter in the range of 10 to 600 μm, preferably 10 to 200 μm, more preferably 10 to 80 μm.

A mechanical alloying process of an alloy of a metal including Co or Co and Cr, or an atomized powder thereof and a metal oxide is carried out to obtain the powder (A). A metal oxide to be used is made of an oxide of a metal element. More specifically, there can be mentioned for instance SiO, SiO₂, TiO₂, Ta₂O₅, Al₂O₃, MgO, CaO, Cr₂O₃, ZrO₂, B₂O₃, Sm₂O₃, HfO₂, and Gd₂O₃. In particular, the metal oxide is preferably an oxide of at least an element of the first kind that is selected from Si, Ti, and Ta. A remaining part can contain other elements without spoiling the effect of the present invention. As the other elements, tantalum, niobium, copper, and neodymium can be mentioned for instance. The mechanical alloying process is carried out by a ball mill most commonly.

A grindability index of the powder (A) is generally in the range of 30 to 95%, preferably in the range of 50 to 95%, more preferably in the range of 80 to 90%. In the case in which the grindability index is in the above range, the powder (A) can be fully refined, and the matrix phase and the metal oxide phase in the target can be uniformly dispersed. Moreover, it is possible to moderately suppress a contamination of impurities such as zirconium and carbon tending to be increased according to an increase in a grindability index.

Moreover, in the case in which Cr is contained as a metal, as substitute for obtaining the powder (A) described above, while the Cr contained powder is directly used, the processes in the subsequent steps can also be carried out. Furthermore, it is preferable that the Cr contained powder contains Co, Cr, and a metal oxide.

In the next place, the powder (A) and Pt is mixed to obtain the powder (B). It is preferable to use a simple substance powder as Pt. Although a mixing method is not restricted in particular, a blender mill mixing is preferable.

A grain size regulation of the powder (B) can also be carried out before moving to a sintering process that is the next step. A vibrating screen is used for the grain size regulation. By carrying out the grain size regulation, the homogeneity of the powder (B) can be further improved.

By sintering the obtained powder (B), a sputtering target in accordance with the present invention can be obtained. A sintering temperature of the sputtering target in accordance with the present invention is generally in the range of 800 to 1050° C., preferably in the range of 900 to 1050° C., more preferably in the range of 950 to 1050° C. A pressure in sintering is generally in the range of 10 to 100 MPa, preferably in the range of 20 to 80 MPa, more preferably in the range of 30 to 60 MPa. It is preferable most commonly that a sintering atmosphere is non oxygen atmosphere, more preferably Ar atmosphere of the non oxygen atmospheres.

Until a sintering temperature reaches the maximum sintering temperature from a start of the sintering, a temperature is increased at a rate generally in the range of 250 to 6000° C./h, preferably in the range of 1000 to 6000° C./h in a period of time in the range of 10 min to 4 h most commonly.

A maximum sintering temperature holding time (sintering time) is in the range of 3 min to 5 h most commonly. In the case in which the maximum sintering temperature holding time is in the above range, a grain growth of the fine grain that is formed by the above matrix phase and the above metal oxide phase can be effectively suppressed, and a relative density of the target to be obtained can be improved.

Moreover, from the above sintering temperature to the range of 200 to 400° C., a temperature is decreased at a rate generally in the range of 300 to 1000° C./hr, preferably in the range of 500 to 1000° C./hr, more preferably in the range of 700 to 1000° C./hr in a period of time in the range of 1 to 3 h most commonly.

A method for manufacturing a sputtering target for a magnetic recording film in accordance with the present invention is characterized in that a sintering temperature is in the above range, and the temperature lowering rate is in the above range, that is, the sputtering target is sintered at a relatively low temperature, and a temperature is lowered at a high speed. Consequently, a grain growth of the grain that is formed by the matrix phase and the metal oxide phase can be effectively suppressed, and the fcc structure that is formed by a crystal that exists in the matrix phase can be effectively held, whereby a quality of a target to be obtained can be improved. As a result, by the method for manufacturing a sputtering target for a magnetic recording film in accordance with the present invention, it is possible to easily obtain a sputtering target in which a magnetic permeability is in the range of 6 to 15 and a relative density is 90% or higher.

In particular, a preferable sintering temperature and a preferable maximum sintering temperature holding time may vary depending on a composition of a sputtering target. More specifically, in the case in which a composition of a sputtering target is composed of Co 66 mole %, Pt 15 mole %, Cr 10 mole %, and TiO₂ 9 mole %, it is preferable that a sintering temperature is in the range of 800 to 950° C., and a maximum sintering temperature holding time (sintering time) is in the range of 3 min to 5 h.

Moreover, in the case in which a composition of a sputtering target is composed of Co 68 mole %, Pt 12 mole %, Cr 8 mole %, and SiO₂ 12 mole %, it is preferable that a sintering temperature is in the range of 900 to 1050° C., and a maximum sintering temperature holding time (sintering time) is in the range of 5 min to 2 h.

Furthermore, in the case in which a composition of a sputtering target is composed of Co 64 mole %, Pt 16 mole %, Cr 16 mole %, and Ta₂O₅ 5 mole %, it is preferable that a sintering temperature is in the range of 980 to 1050° C., and a maximum sintering temperature holding time (sintering time) is in the range of 5 min to 2 h.

In the case in which the above sintering conditions are satisfied, although a sintering method to be adopted is not restricted in particular, it is preferable to adopt an electric current sintering. In the case in which the electric current sintering is used for instance, after a forming die in a predetermined shape is filled with a raw powder, it is possible to adopt the conditions in which a pressure is in the range of 20 to 50 Pa and a sintering time is in the range of 3 min to 5 h in the case in which a sintering temperature is in the range of 800 to 1050° C. Consequently, in the case in which a hot press (HP) method that has been extensively adopted is used to carry out a sintering in a low temperature region, although a grain growth of the grain that is formed by the matrix phase and the metal oxide phase can be suppressed to a certain level, it tends to be hard to obtain a target of a high density. However, in the case in which the electric current sintering is used, the sintering temperature conditions of wide variety of kinds can be easily controlled. Consequently, even in the case in which a sintering at a low temperature is carried out, the grain growth of the grain that is formed by the matrix phase and the metal oxide phase can be suppressed, and it is easy to obtain a target of a high density.

### EMBODIMENTS

The embodiments (examples) of the present invention will be described below in detail. However, the present invention is not restricted to the embodiments. Each evaluation was carried out according to the following procedures.

### <Relative Density>

A relative density was measured based on the Archimedes method. More specifically, an aerial weight of a sputtering target sintered object was divided by a volume (=weight in water for a sputtering target sintered object/water specific gravity at a measured temperature), and a value of a percentage to a theoretical density ρ (g/cm³) that is represented by the above expression (X) was obtained as a relative density (unit: %).

### <Magnetic Permeability>

A magnetic permeability was measured by using the BH tracer (manufactured by TOEI INDUSTRY CO., LTD., an output magnetic field: 1k Oe).

<Average Grain Diameter of a Grain that is Formed by the Matrix Phase and the Metal Oxide Phase>

A cutting plane of a sputtering target was observed by using a scanning analytical electron microscope (manufactured by JEOL Ltd., DATUM Solution Business Operation). For the all grains that were formed by the matrix phase and the metal oxide phase in an SEM image (an accelerating voltage: 20 kV) of 1200 μm×1600 μm and that exist on a line segment of a diagonal line in an image, a maximum grain diameter and a minimum grain diameter were measured, and the maximum grain diameter and the minimum grain diameter were averaged as an average grain diameter for each of the matrix phase and the metal oxide phase.

### <X-Ray Diffraction Peak Intensity Ratio>

By using X-ray diffraction analyzing apparatus (model: MXP3, manufactured by Mac Science Corporation), the X-ray diffraction peak intensity of the Co-fcc [002] face and the X-ray diffraction peak intensity of the Co-hcp [103] face for the obtained sputtering target were measured under the following measuring conditions, and an X-ray diffraction peak intensity ratio was calculated based on the above expression (I).

X-ray source: Cu

### Power: 40 kV, 30 mA

Measuring method: 2θ/θ, continuous scanning
Scanning speed: 4.0 deg/min

### <Number of Particles>

A sputtering processing was carried out by using a sputtering target that has been obtained. A glass was used as a substrate. The glass was disposed on a sputtering apparatus (model: MSL-464, manufactured by TOKKI Corporation), and the sputtering target was sputtered under the following conditions. The number of particles that were generated in the sputtering target of φ2.5 inches was measured.

### Process gas: Ar

process pressure: 10 mTorr
Input electric power: 3.1 W/cm²
Sputtering time: 15 sec

### Embodiment 1

An alloy of CoCr of 2 kg was atomized by injecting an Ar gas of 50 kg/cm² under the condition of a tapping temperature of 1650° C. (measured by using a radiation thermometer) by using a microminiature gas atomizing apparatus (manufactured by NISSIN GIKEN CO., LTD.) to obtain a powder. The obtained powder was a powder in a spherical shape having an average grain diameter of 150 μm or less.

In the next place, by using the obtained powder and a TiO₂ powder (having an average grain diameter of approximately 0.5 μm), a mechanical alloying process was carried out by using a ball mill to obtain the powder (A).

A Pt powder (having an average grain diameter of approximately 0.5 μm) and a powder similar to the Co powder were further input to the obtained powder (A), and the powders were mixed to have a compositional ratio of CO₆₆Cr₁₀Pt₁₅ (TiO₂)₉, whereby the powder (B) was obtained. A ball mill was used for mixing.

Moreover, the grain size regulation of the obtained powder (B) was carried out by using a vibrating screen.

In the next place, the powder (B) was put in a forming die, and was sintered by suing an electric current sintering apparatus under the following conditions.

### [Sintering Conditions]

Sintering atmosphere: Ar atmosphere
Temperature increasing rate: 800° C./hr, temperature increasing time: 1 h
Sintering temperature: 800° C.
Maximum sintering temperature holding time: 10 min

### Pressure: 50 MPa

Temperature decreasing rate: 400° C./hr (from the maximum sintering temperature to 200° C.), temperature decreasing time: 1.5 h

By carrying out a cutting work of the obtained sintered object, a sputtering target of φ4 inches was obtained. The measuring results using the sintered object are shown in Table 1.

### Embodiments 2 to 4, Reference Examples 1 and 2

By using powders similar to those of Embodiment 1, the powders were mixed to have a compositional ratio shown in Table 1, whereby the powder (B) was obtained. Similarly to Embodiment 1 except for the sintering conditions shown in Table 1, a sputtering target of φ4 inches was obtained. The measuring results using the sintered object are shown in Table 1.

### Comparative Example 1

By using powders similar to those of Embodiment 1, the powders were mixed to have a compositional ratio shown in Table 1, whereby the powder (B) was obtained. Similarly to Embodiment 1 except for a sintering under the following conditions, a sputtering target of φ4 inches was then obtained by using a hot press apparatus. The measuring results using the sintered object are shown in Table 1.

Sintering atmosphere: Ar atmosphere
Temperature increasing rate: 450° C./hr, temperature increasing time: 2 h
Sintering temperature: 900° C.
Maximum sintering temperature holding time: 1 h

### Pressure: 30 MPa

Temperature decreasing rate: 150° C./hr (from the maximum sintering temperature to 300° C.), temperature decreasing time: 4 h

### Comparative Examples 2 to 4

By using powders similar to those of Comparative example 1, the powders were mixed to have a compositional ratio shown in Table 1, whereby the powder (B) was obtained. Similarly to Comparative example 1 except for the sintering conditions shown in Table 1, a sputtering target of φ4 inches was obtained. The measuring results using the sintered object are shown in Table 1.

### Embodiments 5 to 7, Reference Examples 3 and 4

By using an SiO₂ powder (having an average grain diameter of approximately 0.5 μm) as substitute for the TiO₂ powder, the powders were mixed to have a compositional ratio shown in Table 1, whereby the powder (B) was obtained. Similarly to Comparative example 1 except for the sintering conditions shown in Table 1, a sputtering target of 0 inches was obtained. The measuring results using the sintered object are shown in Table 1.

### Embodiments 8 and 9

By using a Ta₂O₅ powder (having an average grain diameter of approximately 0.5 μm) as substitute for the TiO₂ powder, the powders were mixed to have a compositional ratio shown in Table 1, whereby the powder (B) was obtained. Similarly to Comparative example 1 except for the sintering conditions shown in Table 1, a sputtering target of 0 inches was obtained. The measuring results using the sintered object are shown in Table 1.

TABLE 1

| | | | | | | Average grain | | | | |
|---|---|---|---|---|---|---|---|---|---|---|
| | | | Maximum | | | diameter | | X-ray | | |
| | | | sintering | | | of grain (μm) | | diffraction peak | | Number |
| | | Sintering | temperature | | Relative | | Metal | intensity ratio | Sputter | of |
| | | temperature | holding time | Magnetic | density | Matrix | oxide | of the | rate | particles |
| | Composition (atom %) | (° C.) | (min) | permeability | (%) | phase | phase | expression (I) | (nm/s) | (pieces) |
| Embodiment 1 | Co66 Cr10 Pt15 (TiO₂)9 | 800 | 10 | 8.1 | 93.0 | 2.1 | 1.6 | 0.900 | — | — |
| Embodiment 2 | Co66 Cr10 Pt15 (TiO₂)9 | 850 | 10 | 9.3 | 96.0 | 2.2 | 1.6 | 0.862 | — | — |
| Embodiment 3 | Co66 Cr10 Pt15 (TiO₂)9 | 950 | 10 | 12.6 | 95.7 | 2.7 | 1.9 | 0.880 | 1.30 | 23 |
| Embodiment 4 | Co64 Cr12 Pt14 (TiO₂)10 | 950 | 60 | 9.7 | 96.9 | 5.2 | 2.9 | 0.816 | — | — |
| Reference | Co66 Cr10 Pt15 (TiO₂)9 | 750 | 10 | 8.2 | 82.0 | 2.4 | 1.8 | 0.882 | 1.10 | 1850 |
| example 1 | | | | | | | | | | |
| Reference | Co66 Cr10 Pt15 (TiO₂)9 | 980 | 10 | 18.2 | 96.7 | 3.8 | 2.1 | 0.682 | 1.13 | 48 |
| example 2 | | | | | | | | | | |
| Comparative | Co62 Cr16 Pt14 (TiO₂)8 | 900 | 60 | 16.3 | 78.3 | 4.0 | 3.0 | 0.872 | — | — |
| example 1 | | | | | | | | | | |
| Comparative | Co62 Cr16 Pt14 (TiO₂)8 | 1100 | 60 | 37.9 | 82.0 | 5.1 | 3.8 | 0.705 | — | — |
| example 2 | | | | | | | | | | |
| Comparative | Co66 Cr10 Pt15 (TiO₂)9 | 1290 | 60 | 24.8 | 96.5 | 7.6 | 4.0 | 0.671 | 1.10 | 42 |
| example 3 | | | | | | | | | | |
| Comparative | Co64 Cr12 Pt14 (TiO₂)10 | 1290 | 120 | 32.3 | 98.7 | 12.0 | 5.8 | 0.592 | — | — |
| example 4 | | | | | | | | | | |
| Embodiment 5 | Co68 Cr8 Pt12 (SiO₂)12 | 950 | 5 | 8.5 | 94.1 | 3.0 | 2.2 | 0.841 | — | — |
| Embodiment 6 | Co68 Cr8 Pt12 (SiO₂)12 | 1000 | 5 | 9.1 | 95.9 | 3.6 | 2.6 | 0.980 | — | — |
| Embodiment 7 | Co68 Cr8 Pt12 (SiO₂)12 | 1050 | 5 | 9.5 | 96.8 | 3.4 | 2.3 | 0.760 | 1.18 | 26 |
| Reference | Co68 Cr8 Pt12 (SiO₂)12 | 850 | 5 | 8.8 | 87.3 | 2.6 | 1.8 | 0.840 | 1.02 | 1630 |
| example 3 | | | | | | | | | | |
| Reference | Co68 Cr8 Pt12 (SiO₂)12 | 1100 | 5 | 16.2 | 98.3 | 7.6 | 4.2 | 0.380 | 1.00 | 48 |
| example 4 | | | | | | | | | | |
| Embodiment 8 | Co64 Cr16 Pt16 (Ta₂O₅)4 | 980 | 10 | 9.0 | 99.1 | 2.1 | 1.5 | 0.880 | 1.06 | 28 |
| Embodiment 9 | Co64 Cr16 Pt16 (Ta₂O₅)4 | 1050 | 5 | 10.1 | 99.3 | 4.1 | 2.3 | 0.917 | — | — |

1. A sputtering target for a magnetic recording film, comprising a matrix phase that includes Co and Pt and a metal oxide phase, wherein a magnetic permeability is in the range of 6 to 15 and a relative density is 90% or higher.

2. The sputtering target for a magnetic recording film as defined in claim 1, wherein an average grain diameter of a grain made of the matrix phase and an average grain diameter of a grain made of the metal oxide phase are both at least 0.05 μm and less than 7.0 μm, and an average grain diameter of a grain made of the matrix phase is larger than an average grain diameter of a grain made of the metal oxide phase in the case in which a surface of the sputtering target is observed by using a scanning analytical electron microscope.

3. The sputtering target for a magnetic recording film as defined in claim 1, wherein an X-ray diffraction peak intensity ratio that is represented by the expression (I) is in the range of 0.7 to 1.0 for an X-ray diffraction analysis:
X-ray diffraction peak intensity ratio=X-ray diffraction peak intensity of the Co-fcc [002] face/{(X-ray diffraction peak intensity of the Co-hcp [103] face+X-ray diffraction peak intensity of the Co-fcc [002] face)} (I)

4. The sputtering target for a magnetic recording film as defined in claim 1, wherein the metal oxide phase includes an oxide of at least one kind of an element that is selected from Si, Ti, and Ta.

5. The sputtering target for a magnetic recording film as defined in claim 1, wherein the matrix phase further includes Cr.

6. The sputtering target for a magnetic recording film as defined in claim 1, wherein the sputtering target is obtained by carrying out a sintering at a sintering temperature in the range of 800 to 1050° C.

7. The sputtering target for a magnetic recording film as defined in claim 1, wherein the sputtering target is obtained by carrying out a sintering based on an electric current sintering.

8. A method for manufacturing a sputtering target for a magnetic recording film comprising a matrix phase that includes Co and Pt and a metal oxide phase, wherein a magnetic permeability is in the range of 6 to 15 and a relative density is 90% or higher,
the method for manufacturing the sputtering target comprising the steps of powdering a metal that includes Co and Pt and a metal oxide, sintering the powder at a sintering temperature in the range of 800 to 1050° C., and lowering a temperature at a rate in the range of 300 to 1000° C./hr.

9. The method for manufacturing a sputtering target for a magnetic recording film as defined in claim 8, further comprising the step of obtaining a sputtering target for a magnetic recording film in which an average grain diameter of a grain made of the matrix phase and an average grain diameter of a grain made of the metal oxide phase are both at least 0.05 μm and less than 7.0 μm, and an average grain diameter of a grain made of the matrix phase is larger than an average grain diameter of a grain made of the metal oxide phase in the case in which a surface of the sputtering target is observed by using a scanning analytical electron microscope.

10. The method for manufacturing a sputtering target for a magnetic recording film as defined in claim 8, further comprising the step of obtaining a sputtering target for a magnetic recording film in which an X-ray diffraction peak intensity ratio that is represented by the expression (I) is in the range of 0.7 to 1.0 for an X-ray diffraction analysis:
X-ray diffraction peak intensity ratio=X-ray diffraction peak intensity of the Co-fcc [002] face/{(X-ray diffraction peak intensity of the Co-hcp [103] face+X-ray diffraction peak intensity of the Co-fcc [002] face)} (I)

11. The sputtering target for a magnetic recording film as defined in claim 8, further comprising the step of obtaining a sputtering target for a magnetic recording film in which the metal oxide phase includes an oxide of at least one kind of an element that is selected from Si, Ti, and Ta.

12. The sputtering target for a magnetic recording film as defined in claim 8, further comprising the step of obtaining a sputtering target for a magnetic recording film in which the matrix phase further includes Cr.

13. The sputtering target for a magnetic recording film as defined in claim 8, further comprising the step of carrying out a sintering based on an electric current sintering.

14. The sputtering target for a magnetic recording film as defined in claim 2, wherein an X-ray diffraction peak intensity ratio that is represented by the expression (I) is in the range of 0.7 to 1.0 for an X-ray diffraction analysis:
X-ray diffraction peak intensity ratio=X-ray diffraction peak intensity of the Co-fcc [002] face/{(X-ray diffraction peak intensity of the Co-hcp [103] face+X-ray diffraction peak intensity of the Co-fcc [002] face)} (I)

15. The sputtering target for a magnetic recording film as defined in claim 2, wherein the metal oxide phase includes an oxide of at least one kind of an element that is selected from Si, Ti, and Ta.

16. The sputtering target for a magnetic recording film as defined in claim 3, wherein the metal oxide phase includes an oxide of at least one kind of an element that is selected from Si, Ti, and Ta.

17. The sputtering target for a magnetic recording film as defined in claim 2, wherein the sputtering target is obtained by carrying out a sintering at a sintering temperature in the range of 800 to 1050° C.

18. The sputtering target for a magnetic recording film as defined in claim 6, wherein the sputtering target is obtained by carrying out a sintering based on an electric current sintering.

19. The method for manufacturing a sputtering target for a magnetic recording film as defined in claim 9, further comprising the step of obtaining a sputtering target for a magnetic recording film in which an X-ray diffraction peak intensity ratio that is represented by the expression (I) is in the range of 0.7 to 1.0 for an X-ray diffraction analysis:
X-ray diffraction peak intensity ratio=X-ray diffraction peak intensity of the Co-fcc [002] face/{(X-ray diffraction peak intensity of the Co-hcp [103] face+X-ray diffraction peak intensity of the Co-fcc [002] face)} (I)

20. The sputtering target for a magnetic recording film as defined in claim 9, further comprising the step of carrying out a sintering based on an electric current sintering.
